(19) United States
(12) Patent Application Publication
(10) Pub. No.: US 2023/0187376 A1
(43) Pub. Date: Jun. 15, 2023

(54) SEMICONDUCTOR MODULE

(71) Applicant: FUJI ELECTRIC CO., LTD., Kawasaki-shi (JP)

(72) Inventors: Naoyuki KANAI, Matsumoto-city (JP); Yuma MURATA, Matsumoto-city (JP)

(73) Assignee: FUJI ELECTRIC CO., LTD., Kawasaki-shi (JP)

(21) Appl. No.: 17/976,373

(22) Filed: Oct. 28, 2022

(30) Foreign Application Priority Data
Dec. 10, 2021 (JP) 2021-200799

(51) Int. Cl. H01L 23/552; H01L 23/48; H01G 2/02; H01R 4/02; H01R 4/70

(52) U.S. Cl. CPC H01L 23/552; H01L 23/48; H01G 2/02; H01R 4/029; H01R 4/70; H01L 25/115

(57) ABSTRACT

A semiconductor module, including: a terminal laminated portion having a first terminal, an insulating member, and a second terminal that are laminated in that order to one another in a laminating direction; and a thermally anisotropic member disposed between the insulating member and the second terminal, the thermally anisotropic member having a thermal conductivity that is higher in a planar direction perpendicular to the laminating direction than in the laminating direction.

### CROSS-REFERENCE TO RELATED APPLICATION

This application is based upon and claims the benefit of priority of the prior Japanese Patent Application No. 2021-200799, filed on Dec. 10, 2021, the entire contents of which are incorporated herein by reference.

### BACKGROUND OF THE INVENTION

### 1. Field of the Invention

The embodiments discussed herein relate to a semiconductor module.

### 2. Background of the Related Art

A semiconductor device includes a semiconductor module and a capacitor. The semiconductor module and the capacitor are electrically connected. The semiconductor module includes a power device and as one example has a power converting function. Example power devices include an insulated gate bipolar transistor (IGBT) and a metal oxide semiconductor field effect transistor (MOSFET). In a semiconductor device of this type, the P terminal and N terminal of the semiconductor module are connected by a busbar to the P terminal and N terminal of the capacitor. Insulating paper is provided between the P terminal and the N terminal to keep the P terminal and the N terminal insulated from each other. The P terminal, the N terminal, and the bus bar are connected by laser welding (see, for example, Japanese Laid-open Patent Publication No. 2021-106235).

When joining the P terminals, the N terminals, and bus bar by laser welding, welded portions may excessively melt due to the heat of the laser. To prevent this, a heat transfer probe is placed in contact near the welding location. The heat transfer probe removes heat generated during welding and suppresses an excessive rise in temperature of the welded portions, thereby preventing melting (see, for example, Japanese Laid-open Patent Publication No. 2009-190067).

As described earlier, insulating paper is provided between the P terminal and the N terminal in the semiconductor module. When a bus bar is joined by laser welding to the P terminal and the N terminal that have the insulating paper sandwiched in between, the insulating paper may become damaged by heat caused by the laser. When the insulating paper becomes damaged, it is no longer possible to keep the P terminal and the N terminal insulated from each other. This means that there is the risk of electrical defects occurring and a drop in the reliability of both the semiconductor module and the semiconductor device that includes the semiconductor module.

### SUMMARY OF THE INVENTION

According to an aspect, there is provided a semiconductor module including: a terminal laminated portion including a first terminal, an insulating member, and a second terminal that are laminated in that order to one another in a laminating direction; and a thermally anisotropic member disposed between the insulating member and the second terminal, the thermally anisotropic member having a thermal conductivity that is higher in a planar direction perpendicular to the laminating direction than in the laminating direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts a semiconductor device according to the first embodiment;

FIG. 2 depicts a semiconductor module according to the first embodiment;

FIG. 3 is a plan view of a terminal laminated portion in the semiconductor module according to the first embodiment;

FIG. 4 is an equivalent circuit diagram of the semiconductor module in the semiconductor device according to the first embodiment;

FIGS. 5A and 5B depict a capacitor according to the first embodiment;

FIG. 6 is a cross-sectional view depicting a connecting mechanism included in the semiconductor device according to the first embodiment;

FIG. 7 is a first cross-sectional view useful in explaining the method of connecting used in the semiconductor device according to the first embodiment;

FIG. 8 is a second cross-sectional view useful in explaining the method of connecting used in the semiconductor device according to the first embodiment;

FIG. 9 is a graph depicting thermal conductivity and instantaneous maximum temperature of an insulating sheet for given thicknesses of a thermally anisotropic sheet included in the semiconductor module of the first embodiment;

FIG. 10 is a graph depicting thermal conductivity and instantaneous maximum temperature of the thermally anisotropic sheet for given thicknesses of the thermally anisotropic sheet included in the semiconductor module according to the first embodiment;

FIG. 11 depicts analysis of heat caused by laser welding of the semiconductor device according to the first embodiment; and

FIG. 12 is a cross-sectional view of connected portions in a semiconductor module according to the second embodiment.

### DETAILED DESCRIPTION OF THE INVENTION

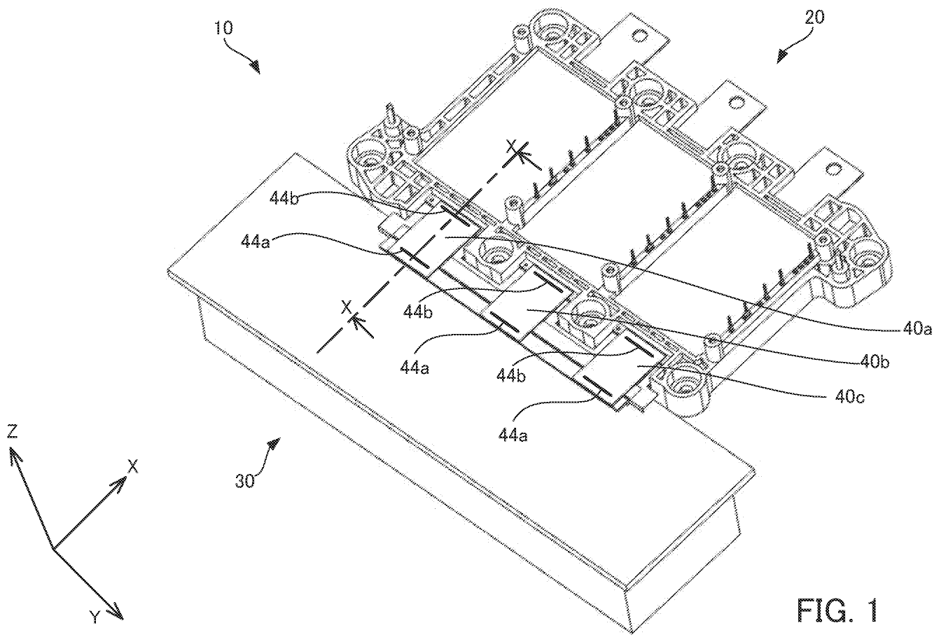

Several embodiments will be described below with reference to the accompanying drawings. Note that in the following description, the expressions “front surface” and “upper surface” refer to an X-Y plane that faces upward (in the “+Z direction”) for a semiconductor device 10 depicted in FIG. 1. In the same way, the expression “up” refers to the upward direction (or “+Z direction”) for the semiconductor device 10 depicted in FIG. 1. The expressions “rear surface” and “lower surface” refer to an X-Y plane that faces downward (in the “−Z direction”) for the semiconductor device 10 depicted in FIG. 1. In the same way, the expression “down” refers to the downward direction (or “−Z direction”) for the semiconductor device 10 depicted in FIG. 1. These expressions are used as needed to refer to the same directions in the other drawings. The expression “high” refers to a higher position (the “+Z direction”) for the semiconductor device 10 depicted in FIG. 1. Likewise, the expression “low” refers to a lower position (in the “−Z direction”) for the semiconductor device 10 depicted in FIG. 1. The expressions “front surface”, “upper surface”, “up”, “rear surface”, “lower surface”, “down”, and “side surface” are merely convenient expressions used to specify relative positional relationships, and are not intended to limit the technical scope of the present embodiments. As one example, “up” and “down” do not necessarily mean directions that are perpendicular to the ground. That is, the “up” and “down” directions are not limited to the direction of gravity. Additionally, in the following description, the expression “main component” refers to a component that composes 80% or higher by volume out of all the components.

### First Embodiment

A semiconductor device according to a first embodiment will now be described with reference to FIG. 1. FIG. 1 depicts the semiconductor device according to the first embodiment. The semiconductor device 10 includes a semiconductor module 20 and a capacitor 30. The semiconductor module 20 and the capacitor 30 are disposed as close as possible to each other so that their respective side portions face each other. Connection members 40a, 40b, and 40c connect the semiconductor module 20 and the capacitor 30 both electrically and mechanically. Laser welding marks 44a and 44b in the form of lines are depicted on the capacitor 30-sides and the semiconductor module 20-sides of the connection members 40a, 40b, and 40c. Note that the number and widths of the connection members 40a, 40b, and 40c are mere examples. The number and widths of the connection members 40a, 40b, 40c are selected according to the number and widths of terminal laminated portions 26a, 26b, and 26c (described later) included in the semiconductor module 20. Note that in the following description, when making no particular distinction between the connection members 40a, 40b, and 40c and the terminal laminated portions 26a, 26b, and 26c, these components are referred to as needed as the “the connection members 40” and the “terminal laminated portions 26”.

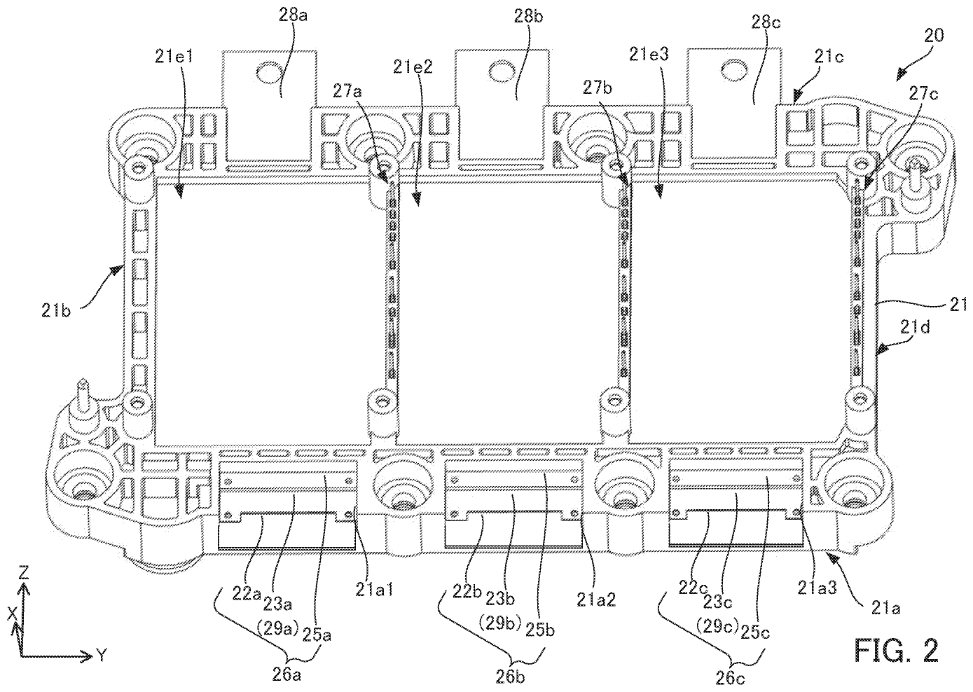

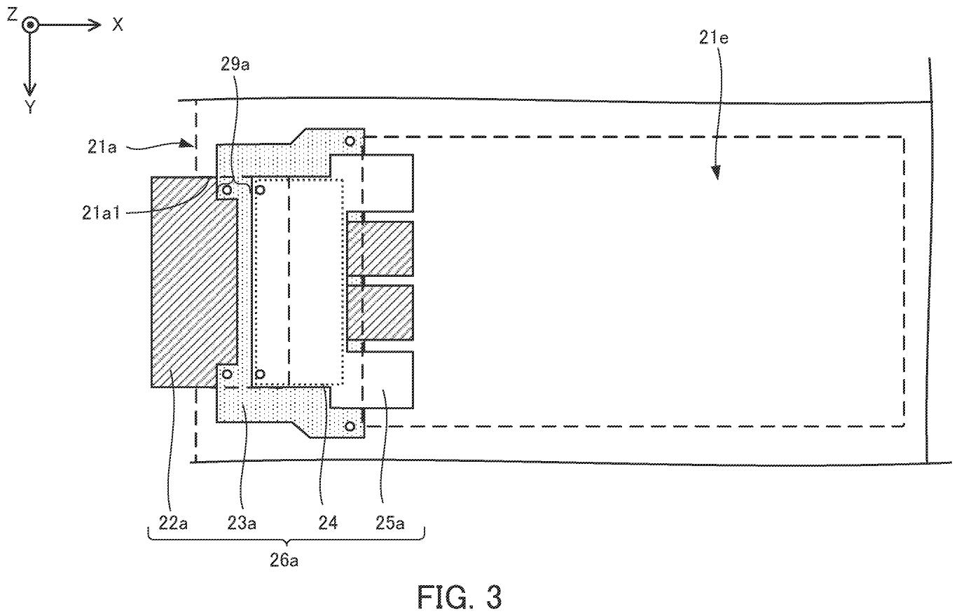

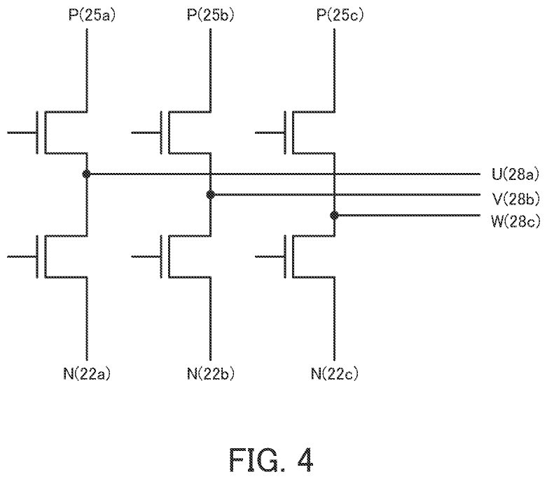

Next, the semiconductor module 20 included in the semiconductor device 10 will be described with reference to FIGS. 2 to 4. FIG. 2 depicts the semiconductor module according to the first embodiment, and FIG. 3 is a plan view of a terminal laminated portion in the semiconductor module according to the first embodiment. FIG. 4 is an equivalent circuit diagram of the semiconductor module in the semiconductor device according to the first embodiment. Note that FIG. 3 depicts a plan view of the terminal laminated portion 26a (a first power terminal 22a, a first insulating sheet 23a, and a second power terminal 25a) of the semiconductor module 20, where a case 21 is indicated using a broken line. Although FIG. 3 depicts only the terminal laminated portion 26a, the terminal laminated portions 26b and 26c are also configured in the same manner.

The semiconductor module 20 has a semiconductor unit (not illustrated) and a case 21 that houses the semiconductor unit. The semiconductor unit includes an insulated circuit board and a semiconductor chip provided on the insulated circuit board. The insulated circuit board includes an insulated board, a heat dissipating plate formed on a rear surface of the insulated board, and a circuit pattern formed on a front surface of the insulated board. The insulated board is made of a ceramic with superior thermal conductivity. Example ceramics include aluminum oxide, aluminum nitride, and silicon nitride that have high thermal conductivity. The heat dissipating plate is made of a metal with superior thermal conductivity. Example metals include aluminum, iron, silver, copper, or an alloy containing at least one of these metals. The circuit pattern is made of a metal with superior electrical conductivity. Examples of such metals include copper and copper alloy. Note that the number and shapes of the circuit patterns are selected as appropriate according to the specification and the like of the semiconductor module 20. As examples of a ceramic circuit board with this configuration, it is possible to use a direct copper bonding (DCB) board or an active metal brazed (AMB) board.

The semiconductor chip includes a switching element, such as an IGBT or a power MOSFET, that is made of silicon, silicon carbide, or gallium nitride. As one example, this semiconductor chip is equipped with a drain electrode (or collector electrode) as a main electrode on a rear surface, and a gate electrode and a source electrode (or an emitter electrode) as main electrodes on a front surface. As needed, the semiconductor chip also includes other components like a free wheeling diode (FWD), such as a Schottky barrier diode (SBD) or a PiN (P-intrinsic-N) diode. This semiconductor chip has a cathode electrode as a main electrode on a rear surface and an anode electrode as a main electrode on the front surface. It is also possible to use an RC (Reverse-Conducting)-IGBT, in which the functions of an IGBT and an FWD are combined, as the semiconductor chip. The number and types of the semiconductor chips are also selected as appropriate according to the specification of the semiconductor module 20.

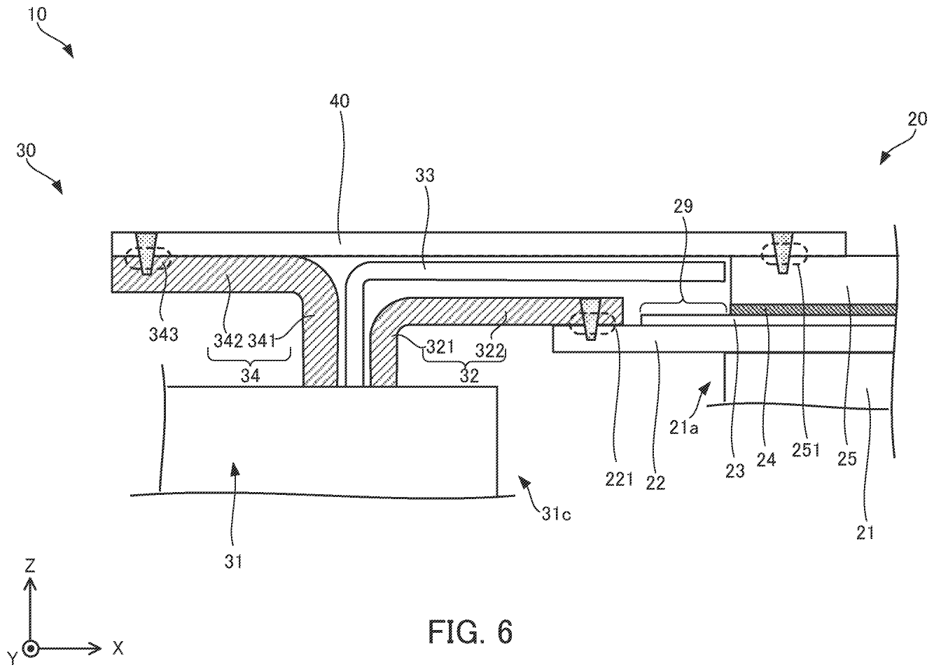

The case 21 is substantially rectangular in plan view and is surrounded on four sides by first to fourth side portions 21a to 21d. The case 21 includes housing regions 21e1, 21e2, and 21e3 along the first side portion 21a. The case 21 includes first power terminals 22a, 22b, and 22c, first insulating sheets 23a, 23b, and 23c, a thermally anisotropic sheet 24 (see FIGS. 3 and 6), and second power terminals 25a, 25b, and 25c. In addition, the case 21 includes a U terminal 28a, a V terminal 28b, and a W terminal 28c. Note that FIG. 3 merely depicts a configuration where the thermally anisotropic sheet 24 is disposed on the first insulating sheet 23a. The thermally anisotropic sheet 24 is disposed on each of the first insulating sheets 23a, 23b, and 23c.

The case 21 of this configuration is formed by injection molding using a thermoplastic resin. On the case 21, control terminals 27a, 27b, and 27c are attached to side portions on the +Y direction sides of the housing regions 21e1, 21e2, and 21e3 in parallel with the shorter direction of the case 21 (that is, the second and fourth side portions 21b and 21d). Examples of the thermoplastic resin used here include polyphenylene sulfide (PPS), polybutylene terephthalate (PBT) resin, polybutylene succinate (PBS) resin, polyamide (PA) resin, and acrylonitrile butadiene styrene (ABS) resin.

The control terminals 27a, 27b, and 27c are also configured to include predetermined terminals by injection molding using a thermoplastic resin. Note that when no particular distinction is made, the housing regions 21e1, 21e2, and 21e3, the first power terminals 22a, 22b and 22c, and the second power terminals 25a, 25b, and 25c are respectively referred to in the following description as the “housing regions 21e”, the “first power terminals 22”, and the “second power terminals 25”. The first insulating sheets 23a, 23b, and 23c, described later, are also referred to in the same way as the “first insulating sheets 23”.

The housing regions 21e1, 21e2, and 21e3 are spaces provided along the longer direction (that is, the first and third side portions 21a and 21c) of the case 21 with the control terminals 27a and 27b as partitions at intermediate positions on the case 21 in plan view. The semiconductor units described earlier are individually housed in these housing regions 21e1, 21e2, and 21e3. In the respective housing regions 21e1, 21e2, and 21e3, the semiconductor units are electrically connected to the first power terminals 22a, 22b, and 22c, the second power terminals 25a, 25b, and 25c, the U terminal 28a, the V terminal 28b, and the W terminal 28c. The semiconductor units are also electrically connected to the control terminals 27a, 27b, and 27c. Wiring members (as examples, bonding wires and lead frames) are used to make these electrical connections. The wiring members are made of a material with superior electrical conductivity. Examples of such materials include metals (such as aluminum and copper) and alloys containing at least one of these metals.

When the semiconductor units have been housed in this way, the insides of the housing regions 21e1, 21e2, and 21e3 are encapsulated using an encapsulating resin as depicted in FIG. 2. The encapsulating member contains a thermosetting resin and a filler included within the thermosetting resin. Example thermosetting resins include epoxy resin, phenolic resin, and maleimide resin. Example fillers include silicon oxide, aluminum oxide, boron nitride, and aluminum nitride.

First end portions of the front surfaces of the first power terminals 22a, 22b, and 22c are exposed along the length direction (the first side portion 21a) to terminal regions 21a1, 21a2, and 21a3, respectively of the first side portion 21a of the case 21. Here, the first end portions of the first power terminals 22a, 22b, and 22c protrude outward (in the −X direction) from the first side portion 21a. Second end portions of the first power terminals 22a, 22b, and 22c are electrically connected to locations inside the case 21 that correspond to the N terminals of the semiconductor chips. The first power terminals 22a, 22b, and 22c are shaped as flat plates on at least the first side portion 21a side. The first power terminals 22a, 22b, and 22c are made of a metal with superior electrical conductivity. Example metals include copper and copper alloy.

The second power terminals 25a, 25b, and 25c are disposed on the first power terminals 22a, 22b, and 22c with the first insulating sheets 23a, 23b, and 23c disposed in between, so as to expose the first end portions of the first power terminals 22a, 22b, and 22c. Note that front end portions (or “terrace portions 29a, 29b, and 29c”) of the first insulating sheets 23a, 23b, and 23c are positioned between front end portions of the first power terminals 22a, 22b, and 22c and front end portions of the second power terminals 25a, 25b, and 25c. With this configuration, the first power terminals 22a, 22b, and 22c and the second power terminals 25a, 25b, and 25c are kept insulated from each other.

The first insulating sheets 23a, 23b, and 23c are made of an insulating material that provides electrical insulation. As examples of the insulating material, insulating paper made of a wholly aromatic polyamide polymer, or a sheet-like material made of a fluorine-based or polyimide-based resin material may be used. Note that when no particular distinction is made, the terrace portions 29a, 29b, and 29c are referred to as the “terrace portions 29”.

The thermally anisotropic sheet 24 is made of a material with thermal conductivity that is higher in a planar direction (that is, any direction across an X-Y plane), which is perpendicular to a laminating direction (or “±Z direction”) in which the terminal laminated portions 26a, 26b, and 26c are laminated, than in the laminating direction itself. As one example, this material includes graphite as a main component. The thermally anisotropic sheet 24 is disposed in at least a range indicated by a broken line in FIG. 3. That is, in plan view, the thermally anisotropic sheet 24 is provided under regions where the second power terminals 25a, 25b, and 25c are exposed without protruding from the second power terminals 25a, 25b, and 25c. The thermally anisotropic sheet 24 will be described in detail later.

First end portions of the front surfaces of the second power terminals 25a, 25b, and 25c are exposed along the length direction (the first side portion 21a) to the first side portion 21a of the case 21. In addition, in plan view, exposed portions of the second power terminals 25a, 25b, and 25c on the first end portion side overlap the thermally anisotropic sheet 24. Second end portions of the second power terminals 25a, 25b, and 25c are electrically connected to locations inside the case 21 corresponding to the P terminals of the semiconductor chips. The second power terminals 25a, 25b, and 25c are formed as flat plates on at least the first side portion 21a side. The second power terminals 25a, 25b, and 25c are made of a metal with superior electrical conductivity. Example metals include copper and copper alloy.

In this way, the first power terminals 22a, 22b, and 22c, the first insulating sheets 23a, 23b, and 23c, the thermally anisotropic sheet 24, and the second power terminals 25a, 25b, and 25c are laminated in that order to construct the terminal laminated portions 26a, 26b, and 26c. When doing so, edge portion regions of the front surfaces of the first power terminals 22a, 22b, and 22c, the first insulating sheets 23a, 23b, and 23c, and the second power terminals 25a, 25b, and 25c on the first side portion 21a side are all exposed. Note that an end surface on the first side portion 21a-side of the thermally anisotropic sheet 24 may also be exposed.

As described later with reference to FIGS. 6A and 6B, boundary positions of the first power terminals 22a, 22b, and 22c (indicated as the “first power terminal 22” in FIG. 6) that are directly below the front end portions of the first insulating sheets 23a, 23b, and 23c are separated by a predetermined distance from the front end portions of the second power terminals 25a, 25b, and 25c (indicated as the “second power terminal 25” in FIG. 6). That is, the distance by which the front end portions of the first insulating sheets 23a, 23b, and 23c extend beyond the front end portions of the second power terminals 25a, 25b, and 25c toward the exposed surfaces of the first power terminals 22a, 22b, 22c is adjusted. By doing so, a sufficient creepage distance is maintained between the first power terminals 22a, 22b, and 22c and the second power terminals 25a, 25b, and 25c. Note that this distance varies depending on the withstand voltage of the semiconductor device 10. As one example, the distance is at least 3 mm but not greater than 14.5 mm. Alternatively, the distance may be at least 6 mm but not greater than 12.5 mm. In addition, for a withstand voltage of 750V, the distance may be 7.5 mm plus a tolerance of 0.5 mm, and for a withstand voltage of 1200V, the distance may be 12 mm plus a tolerance of 0.5 mm.

First end portions of the control terminals 27a, 27b, and 27c extend upward (in the +Z direction) of the semiconductor module 20. Second end portions of the control terminals 27a, 27b, and 27c are electrically connected to the gate electrodes (control electrodes) of the semiconductor chips of the respective semiconductor units in the housing regions 21e1, 21e2, and 21e3, respectively. The control terminals 27a, 27b, and 27c are made of a metal with superior electrical conductivity. Example metals include copper, copper alloy, aluminum, and aluminum alloy.

Second end portions of the U terminal 28a, the V terminal 28b, and the W terminal 28c are electrically connected to the source electrodes (or emitter electrodes) of the semiconductor chips of the respective semiconductor units inside the housing regions 21e1, 21e2, and 21e3. First end portions of the U terminal 28a, the V terminal 28b, and the W terminal 28c are exposed along the length direction (the third side portion 21c) of the case 21 to the third side portion 21c of the case 21. The U terminal 28a, the V terminal 28b, and the W terminal 28c are made of a metal with superior electrical conductivity. Example metals include copper and copper alloy.

The semiconductor module 20 includes an equivalent circuit depicted in FIG. 4. Note that in FIG. 4, a switching element may be used, with power MOSFETs or IGBT used as the semiconductor chips. In the semiconductor module 20, the second power terminals 25a, 25b, and 25c, which are P terminals, are electrically connected to the collector electrodes of the semiconductor chips of the respective semiconductor units inside the housing regions 21e1, 21e2, and 21e3. The U terminal 28a, the V terminal 28b, and the W terminal 28c are electrically connected to the emitter electrodes of the semiconductor chips of the respective semiconductor units inside the housing regions 21e1, 21e2, and 21e3. The first power terminals 22a, 22b, and 22c, which are N terminals, are electrically connected to the emitter electrodes of the semiconductor chips of the respective semiconductor units inside the housing regions 21e1, 21e2, and 21e3.

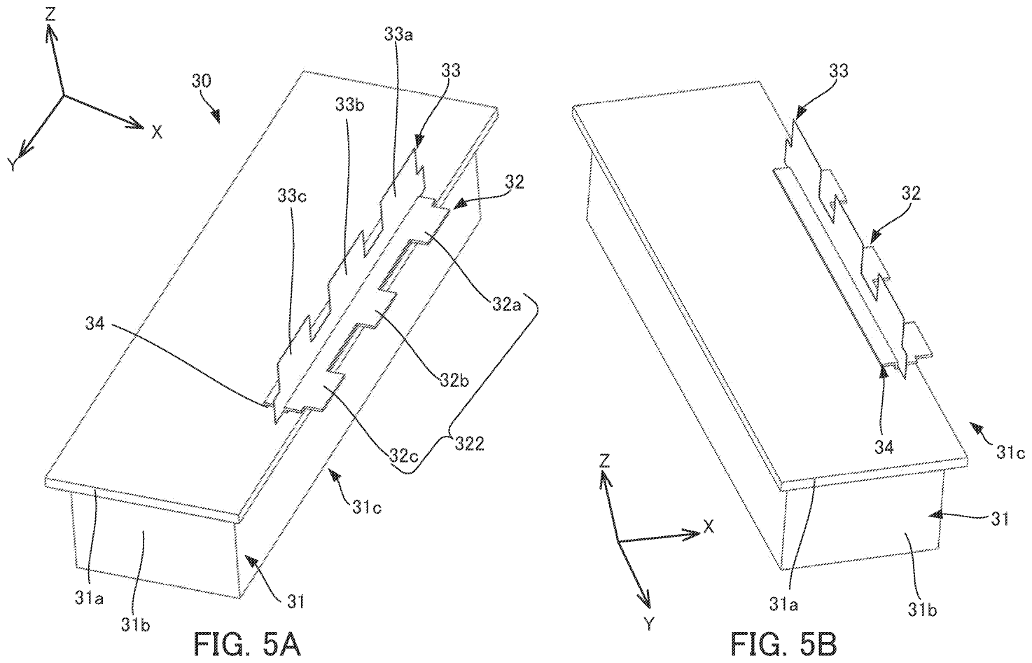

Next, the capacitor 30 will be described with reference to FIGS. 5A and 5B. FIGS. 5A and 5B depict a capacitor according to the first embodiment. Note that FIG. 5A is a perspective view of the capacitor 30, and FIG. 5B is a perspective view of the capacitor 30 from the opposite direction to FIG. 5A. The capacitor 30 includes a case 31, a first connection terminal 32, a second insulating sheet 33, and a second connection terminal 34.

The case 31 is the main body of the capacitor. The case 31 is composed of a lid portion 31a and a storage case 31b, with the first connection terminal 32, the second insulating sheet 33, and the second connection terminal 34 disposed on the lid portion 31a. A plurality of capacitors that each have an N pole and a P pole are housed inside the storage case 31b. One example material of the lid portion 31a and the storage case 31b is epoxy resin. A second end portion of the first connection terminal 32 is electrically connected to all of the N poles of capacitor elements inside the case 31. A first end portion of the first connection terminal 32 extends outside the case 31 toward a fifth side portion 31c. A part of the first connection terminal 32 that extends from the case 31 is substantially L-shaped in side view. As described later with reference to FIG. 6, the substantially L-shaped first connection terminal 32 includes a first conductive portion 321 and a first wiring portion 322. A second end portion of the first conductive portion 321 is electrically connected to the N poles of the capacitor elements inside the case 31 and extends vertically to the outside from the front surface of the lid portion 31a of the case 31. The first wiring portion 322 is substantially perpendicular to the first conductive portion 321 and extends substantially parallel to the front surface of the lid portion 31a of the case 31 toward the fifth side portion 31c. In addition, the part (or “first wiring portion 322”) of the first connection terminal 32 that extends from the lid portion 31a of the case 31 is divided into a first connection part 32a, a second connection part 32b, and a third connection part 32c and therefore shaped like the teeth of a comb in plan view. Note that the reference numerals of the first connection part 32a, the second connection part 32b, and the third connection part 32c have been omitted from FIG. 5B. The widths of the first connection part 32a, the second connection part 32b, and the third connection part 32c respectively correspond to the widths of the housing regions 21e1, 21e2, and 21e3 (that is, the first power terminals 22a, 22b, and 22c) of the semiconductor module 20. The first connection terminal 32 is made of a metal with superior electrical conductivity. Example metals include copper and copper alloy.

Second end portions of the second connection terminals 34 are all electrically connected to the P poles of the capacitor elements inside the case 31. A first end portion of the second connection terminal 34 extends outside from the fifth side portion 31c on the front surface of the case 31. The second connection terminal 34 is provided at a distance from the first connection terminal 32 toward the opposite side of the fifth side portion 31c. A part of the second connection terminal 34 that extends from the case 31 is substantially L-shaped in side view. As will be described later with reference to FIG. 6, the substantially L-shaped second connection terminal 34 includes a second conductive portion 341 and a second wiring portion 342. The second conductive portion 341 has a second end portion that is electrically connected to the P poles of the capacitor elements inside the case 31 and extends vertically to the outside from the front surface of the case 31. The second wiring portion 342 is substantially perpendicular to the second conductive portion 341 and extends substantially parallel to the front surface of the case 31 toward the opposite side to the fifth side portion 31c. The second connection terminal 34 is made of a metal with superior electrical conductivity. Example metals include copper and copper alloy.

The second insulating sheet 33 is longer than the first connection terminal 32 and extends from a position on the case 31 between the first connection terminal 32 and the second connection terminal 34 to the outside. Accordingly, on the outside of the case 31, the first connection terminal 32 and the second connection terminal 34 are kept insulated from each other by the second insulating sheet 33. The second insulating sheet 33 is made of an insulating material that is flexible and is electrically insulating. As examples of this insulating material, insulating paper made of a wholly aromatic polyamide polymer, or a sheet-like material made of a fluorine-based or polyimide-based resin material is used.

The front end portion of the second insulating sheet 33 is divided into a first attachment part 33a, a second attachment part 33b, and a third attachment part 33c and therefore shaped like the teeth of a comb in plan view. Note that the reference numerals of the first attachment part 33a, the second attachment part 33b, and the third attachment part 33c have been omitted in FIG. 5B. The widths of the first attachment part 33a, the second attachment part 33b, and the third attachment part 33c correspond to the widths of the housing regions 21e1, 21e2, and 21e3 (that is, the first insulating sheets 23a, 23b, and 23c), respectively, of the semiconductor module 20.

Although not illustrated, the case 31 is also provided with other terminals. These terminals are electrically connected at second end portions thereof to the positive and negative terminals of all of the capacitor elements inside the case 31. First end portions of the respective terminals extend outside the case 31. The positions on the case 31 where the terminals protrude may be any position aside from the first connection terminal 32 and the second connection terminal 34. As one example, the terminals are provided along a side portion on an opposite side of the fifth side portion 31c. The terminals are made of a metal with superior electrical conductivity. Example metals include copper and copper alloy.

Next, the connection members 40a, 40b, and 40c will be described (see FIG. 1). The connection members 40a, 40b, and 40c are shaped as flat plates in plan view. The widths of first end portions of the connection members 40a, 40b, and 40c correspond to the widths of the housing regions 21e1, 21e2, and 21e3 (that is, the second power terminals 25a, 25b, and 25c) of the semiconductor module 20. The thicknesses of the connection members 40a, 40b, and 40c are set thinner than the thicknesses of the second power terminals 25a, 25b, and 25c. The first end portions of the connection members 40a, 40b, and 40c are joined by laser welding to the second power terminals 25a, 25b, and 25c. Second end portions of the connection members 40a, 40b, and 40c are joined by laser welding to the second connection terminal 34 of the capacitor 30. This joining by laser welding may be performed by a seam laser that continuously emits laser light or a spot laser that emits pulsed laser light. FIG. 1 depicts a case where joining has been performed by a seam laser. For this reason, laser welding marks 44a and 44b in the form of straight lines are indicated on the respective capacitor 30-sides and semiconductor module 20-sides of the connection members 40a, 40b, and 40c in FIG. 1. The connection members 40a, 40b, and 40c are made of a metal with superior electrical conductivity. Example metals include copper and copper alloy. Note that in the first embodiment, the three connection members 40a, 40b, and 40c are respectively joined to the second power terminals 25a, 25b and 25c. However, the present embodiments are not limited to this, and like the first connection terminal 32 and the second insulating sheet 33, a semiconductor module 20-side end portion of a connection member that is flat may be divided in the shape of teeth of a comb so as to correspond to the second power terminals 25a, 25b and 25c.

Next, a mechanism that connects the semiconductor module 20 and the capacitor 30 of the semiconductor device 10 will be described with reference to FIG. 6. FIG. 6 is a cross-sectional view depicting a connecting mechanism included in the semiconductor device according to the first embodiment. Note that FIG. 6 is a cross-sectional view taken along a dot-dash line X-X indicated in FIG. 1. Note also that the other connection members 40b and 40c of the semiconductor device 10 in FIG. 1 have the same cross-sectional configuration as FIG. 6.

In the semiconductor device 10, the first wiring portion 322 of the first connection terminal 32 of the capacitor 30 is joined to first joining regions 221 of the first power terminals 22 of the semiconductor module 20. That is, although not illustrated, the first connection part 32a, the second connection part 32b, and the third connection part 32c of the first wiring portion 322 of the first connection terminal 32 are connected to the respective first joining regions of the first power terminals 22a, 22b, and 22c of the semiconductor module 20. Note that the expression “first joining regions 221” is used as a general name for the respective first joining regions of the first power terminals 22a, 22b, and 22c.

The second insulating sheet 33 of the capacitor 30 covers the first connection terminal 32 from above and is bent toward the semiconductor module 20. With respect to the parts that extend outward from the capacitor 30, the second insulating sheet 33 is longer than the first connection terminal 32. The front end portion of the second insulating sheet 33 extends to cover as far as the terrace portion 29 of the first insulating sheet 23 of the semiconductor module 20. The front end portion of the second insulating sheet 33 extends to just before the second power terminal 25. That is, a gap is present between the terrace portion 29 and the front end portion of the second insulating sheet 33 or between the front end portion of the second insulating sheet 33 and the connection members 40. The gap from the front end surface of the first connection terminal 32 to the front end surface of the second power terminal 25 here is at least 6 mm but not greater than 12.5 mm. Note that the terrace portion 29 extends in a direction from a second joining region 251, described later, toward a first joining region 221, also described later, in plan view. Although not illustrated, the first attachment part 33a, the second attachment part 33b, and the third attachment part 33c at the front end portion of the second insulating sheet 33 extend to cover the first insulating sheets 23a, 23b, and 23c of the semiconductor module 20.

The front surface of the second wiring portion 342 of the second connection terminal 34 of the capacitor 30 is flush with the front surface of the second power terminal 25 of the semiconductor module 20. A first end portion of each connection member 40 is connected to a third joining region 343 of the second wiring portion 342 of the second connection terminal 34 of the capacitor 30, and a second end portion of each connection member 40 is joined to the second joining region 251 of the second power terminal 25 of the semiconductor module 20. When doing so, the second joining region 251 and the third joining region 343 are disposed in parallel to the first joining region 221. Also, although not illustrated, second end portions of the connection members 40a, 40b, and 40c are joined to second joining regions of the second power terminals 25a, 25b, and 25c of the semiconductor module 20. Note that the expression “second joining region 251” is a general term for the respective second joining regions of the second power terminals 25a, 25b, and 25c. With the above configuration, the connection members 40 electrically connect the second connection terminal 34 of the capacitor 30 and the second power terminals 25 of the semiconductor module 20. Gaps are formed between a rear surface of the connection members 40 and the front surface of the first wiring portion 322 of the first connection terminal 32 of the capacitor 30. The second insulating sheet 33 is provided in this gap. This means that the first connection terminal 32 is kept insulated from the connection members 40 and the second connection terminal 34. The second insulating sheet 33 is not limited to the state depicted in FIGS. 6A and 6B and may be in contact with the rear surfaces of the connection members 40, the front surface of the first connection terminal 32, and the front end portions of the second power terminals 25 in this gap.

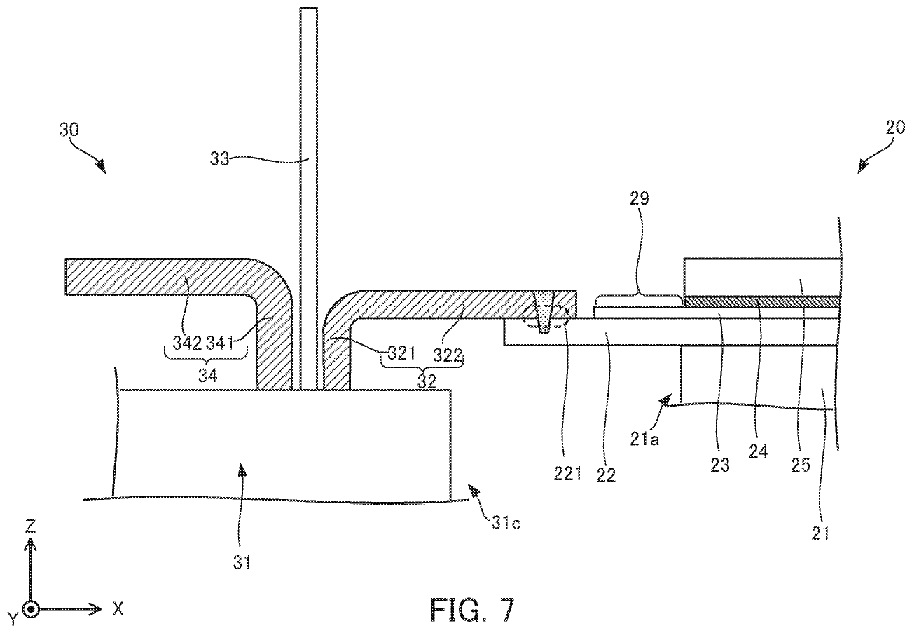

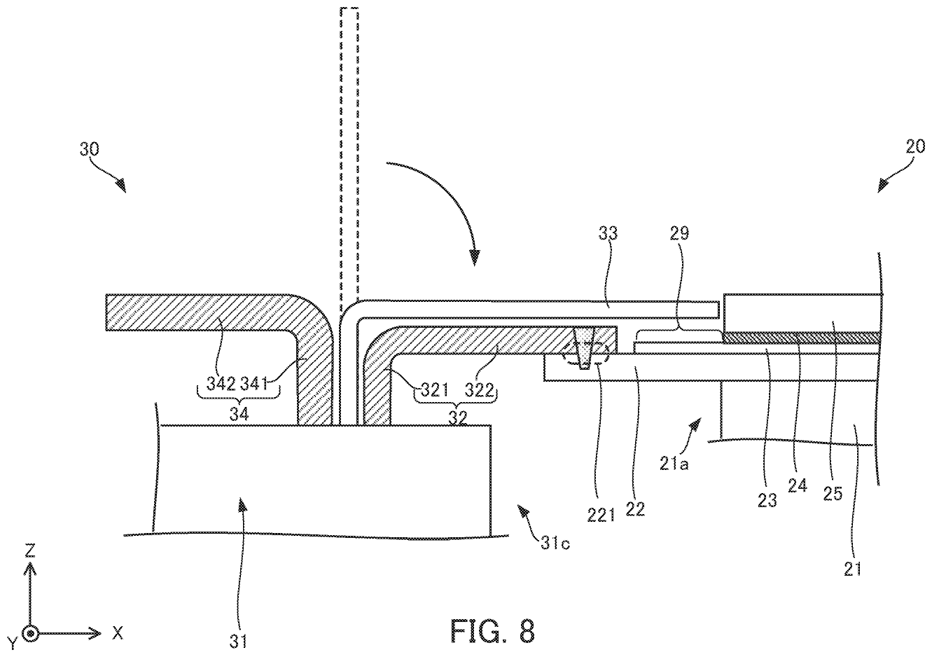

Next, a method of connecting the semiconductor module 20 and the capacitor 30 in the semiconductor device 10 will be described with reference to FIGS. 7 and 8, in addition to FIG. 6. FIGS. 7 and 8 are cross-sectional views useful in explaining the method of connecting used in the semiconductor device according to the first embodiment.

First, the front end portions of the first wiring portion 322 of the first connection terminal 32 of the capacitor 30 is positioned on the first power terminals 22 of the semiconductor module 20. When doing so, the front surface of the second wiring portion 342 of the second connection terminal 34 of the capacitor 30 is flush with the front surface of the second power terminals 25 (the second power terminals 25a, 25b, and 25c) of the semiconductor module 20. In this state, the front end portions of the first wiring portion 322 are joined to the first joining regions 221 of the first power terminals 22 by laser welding (see FIG. 7). The first power terminals 22 protrude from the first side portion 21a. No components that are affected by heat are located around the first joining region 221 of the first power terminal 22. This means that the heat generated by the laser welding has hardly any effect on other components.

Also, as described earlier the first wiring portion 322 is divided into the first connection part 32a, the second connection part 32b, and the third connection part 32c and therefore shaped like the teeth of a comb in plan view. For this reason, the first connection part 32a, the second connection part 32b, and the third connection part 32c of the first wiring portion 322 are respectively joined to the first joining regions of the first power terminals 22a, 22b, and 22c of the terminal regions 21a1, 21a2, and 21a3. Note that the first power terminals 22a, 22b, and 22c are present on the rear of the first connection part 32a, the second connection part 32b, and the third connection part 32c.

Next, the second insulating sheet 33 of the capacitor 30 is bent over toward the semiconductor module 20. When bending over the second insulating sheet 33, it is possible to perform the bending in a single operation due to the flexibility of the second insulating sheet 33. After this bending, the front end portions of the second insulating sheet 33 become positioned over the terrace portions 29 of the first insulating sheets 23 that are exposed between the first power terminals 22 and the second power terminals 25 of the semiconductor module 20 (see FIG. 8). Note that the bent-over second insulating sheet 33 may contact the first power terminals 22, the first insulating sheets 23, and the second power terminals 25. Also, as described earlier, the front end portion of the second insulating sheet 33 is divided into the first attachment part 33a, the second attachment part 33b, and the third attachment part 33c and therefore shaped like the teeth of a comb in plan view. This means that the first attachment part 33a, the second attachment part 33b, and the third attachment part 33c of the second insulating sheet 33 cover the first insulating sheets 23a, 23b, and 23c, respectively. Note that the first insulating sheets 23a, 23b, and 23c are present on the rear surfaces of the first attachment part 33a, the second attachment part 33b, and the third attachment part 33c, respectively, of the second insulating sheet 33.

Next, the first end portion and the second end portion of the connection members 40 are respectively set on the front surface of the second wiring portion 342 of the second connection terminal 34 of the capacitor 30 and the front surfaces of the second power terminals 25 of the semiconductor module 20. After this, the first end portions and the second end portions of the connection members 40 are respectively joined by laser welding to the front surface of the second wiring portion 342 of the capacitor 30 and the front surfaces of the second power terminals 25 of the semiconductor module 20 (see FIG. 6). When doing so, no components that are affected by heat are located around the second wiring portion 342 of the second connection terminal 34. This means that the heat generated by the laser welding has hardly any effect on other components.

Since the thickness of the connection members 40 is thinner than the thickness of the second power terminal 25, it is possible to perform the laser welding more efficiently. However, heat will propagate from the second joining region 251 that is laser welded toward the case 21 (that is, in the −Z direction). The semiconductor module 20 is provided with the thermally anisotropic sheet 24 between the second power terminals 25 and the first insulating sheets 23. Heat from the second joining region 251 is transmitted across the X-Y plane by the thermally anisotropic sheet 24, which suppresses transmission of heat to the first insulating sheet 23. This means that it is possible to suppress damage to the first insulating sheet 23 due to the heat caused by laser welding. Accordingly, it is possible to keep the first power terminals 22 and the second power terminals 25 insulated from each other.

The connection members 40a, 40b, and 40c respectively join the second power terminals 25a, 25b, and 25c of the semiconductor module 20 to the second wiring portion 342 of the second connection terminal 34 of the capacitor 30. By doing so, the semiconductor device 10, in which the semiconductor module 20 and the capacitor 30 are connected, is obtained (see FIG. 1).

Next, the conditions for preventing heat caused by laser welding when connecting the semiconductor module 20 to the capacitor 30 from affecting the first insulating sheets 23a, 23b, and 23c will be described. The thickness and the thermal conductivity in a direction across the X-Y plane of the thermally anisotropic sheet 24 are set at predetermined values so that when the second power terminals 25a, 25b, 25c are heated, the maximum temperature of the surface of the thermally anisotropic sheet 24 that faces the first insulating sheets 23a, 23b, and 23c is not greater than the heat resistance temperature of the thermally anisotropic sheet 24.

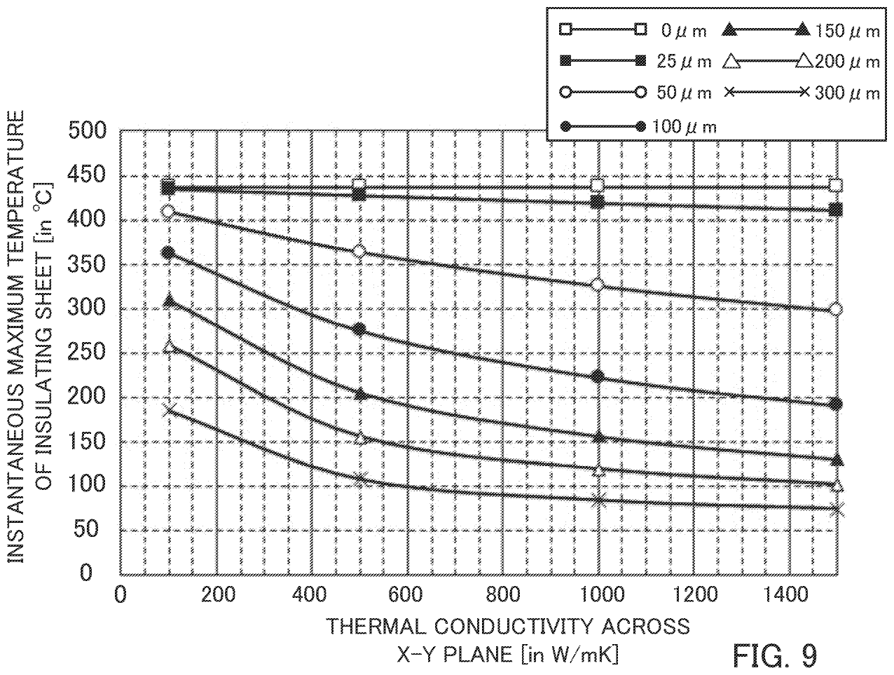

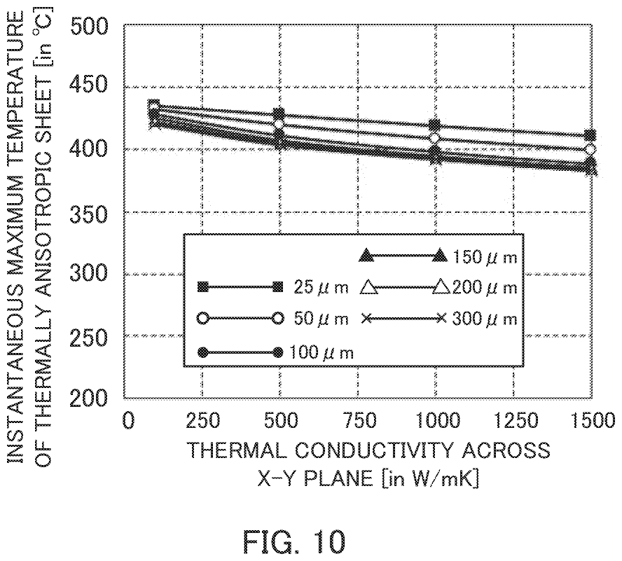

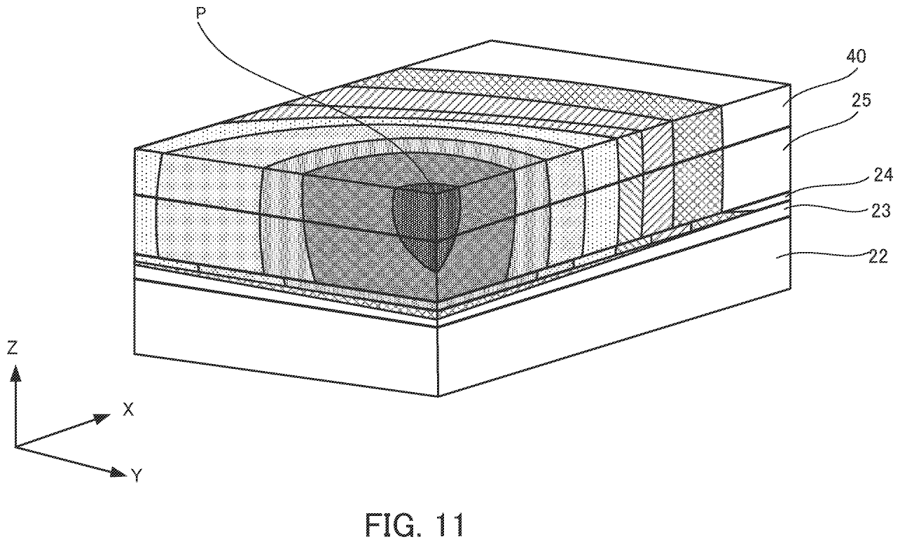

The relationship between temperature and changes in thermal conductivity for given thicknesses of the thermally anisotropic sheet 24 will now be described with reference to FIGS. 9 to 11. FIG. 9 is a graph depicting the thermal conductivity and the instantaneous maximum temperature of the insulating sheet for given thicknesses of the thermally anisotropic sheet included in the semiconductor module of the first embodiment, and FIG. 10 is a graph depicting the thermal conductivity and the instantaneous maximum temperature of the thermally anisotropic sheet for given thicknesses of the thermally anisotropic sheet included in the semiconductor module according to the first embodiment. FIG. 11 depicts analysis of heat caused by laser welding of the semiconductor device according to the first embodiment.

Note that the graph in FIG. 9 depicts results for where no thermally anisotropic sheet 24 was provided (indicated as “0 μm”) and for where the thickness of the thermally anisotropic sheet 24 was 25 μm, 50 μm, 100 μm, 150 μm, 200 μm, and 300 μm, respectively. The X axis in FIG. 9 represents thermal conductivity (in W/mK) in a direction across the X-Y plane, and the Y axis represents the instantaneous maximum temperature (in ° C.) of the first insulating sheet 23 with respect to the thermal conductivity.

The graph in FIG. 10 depicts results for when the thickness of the thermally anisotropic sheet 24 was 25 μm, 50 μm, 100 μm, 150 μm, 200 μm and 300 μm, respectively. The X axis of FIG. 10 represents the thermal conductivity (in W/mK) in a direction across the X-Y plane, and the Y axis represents the instantaneous maximum temperature (° C.) of the thermally anisotropic sheet 24 with respect to the thermal conductivity.

Here, for a configuration where the first power terminals 22, the first insulating sheets 23, the thermally anisotropic sheet 24, the second power terminals 25, and the connection members 40 are laminated in that order as depicted in FIG. 6, the instantaneous maximum temperatures of the first insulating sheet 23 and the thermally anisotropic sheet 24 were analyzed for when laser welding was performed by irradiating a laser in a direction perpendicular to the front surfaces of the connection members 40 that are the top layer. FIG. 11 schematically depicts the results of thermal analysis for this structure under predetermined conditions. In FIG. 11, a point P is the position where laser welding is being performed. In this analysis, the amount of heat inputted by laser welding is around 86 J. The first and second power terminals 22 and 25 are each made of copper and have a thickness of around 1.5 mm. The first and second power terminals 22 and 25 have a specific heat of 0.39 J/gK and a thermal conductivity of 401 W/mk.

The thickness of the first insulating sheet 23 is around 0.38 mm. The first insulating sheet 23 has a specific heat of 1.21 J/gK and a thermal conductivity of 0.15 W/mk. The thickness of the connection members 40 is around 0.8 mm. The connection members 40 are made of copper in the same way as the first and second power terminals 22 and 25. This means that the specific heat and thermal conductivity of the connection members 40 are the same as for the first and second power terminals 22 and 25.

Here, the maximum temperature (or “instantaneous maximum temperature”) reached by the first insulating sheet 23 for different thicknesses of the thermally anisotropic sheet 24 was analyzed. Note that in FIG. 9, when the thermally anisotropic sheet 24 is not provided, the instantaneous maximum temperature and the thermal conductivity at the welding position on the boundary between a member corresponding to the second power terminal 25 and a member corresponding to the connection members 40 are depicted.

The thermally anisotropic sheet 24 in this case is made of graphite and has a thickness of 0.34 mm. The thermally anisotropic sheet 24 has a specific heat of 0.85 J/gK and a thermal conductivity (in the ±Z direction) of 5 W/mk. The heat resistance temperature of the thermally anisotropic sheet 24 in the atmosphere is around 450° C. This means that the thermally anisotropic sheet 24 will become damaged when this heat resistance temperature is exceeded. For this reason, the energy applied to the second power terminal 25 and the thickness of the second power terminal 25 are adjusted to predetermined values to keep the maximum temperature of the surface of the second power terminal 25 facing the thermally anisotropic sheet 24 when the second power terminal 25 is heated not greater than the heat resistance temperature of the thermally anisotropic sheet 24.

From the graph of FIG. 9, it may be understood that the larger the thickness of the thermally anisotropic sheet 24 and the higher the thermal conductivity in directions across the X-Y plane, the larger the drop in the instantaneous maximum temperature of the first insulating sheet 23. The heat resistance temperature of the first insulating sheet 23 depends on the material of the first insulating sheet 23. In addition to the material of the first insulating sheet 23, it is desirable to appropriately select the thermal conductivity and thickness of the thermally anisotropic sheet 24. Note that from the graph in FIG. 10, it may also be understood that the greater the thickness of the thermally anisotropic sheet 24 and the higher the thermal conductivity in directions across the X-Y plane, the larger the drop in the instantaneous maximum temperature of the thermally anisotropic sheet 24.

As examples, the heat resistance temperature of the first insulating sheet 23 may be 300° C. or 260° C. When the heat resistance temperature of the first insulating sheet 23 is 300° C., from the graph of FIG. 9, it is preferable for the thermal conductivity in directions across the X-Y plane of the thermally anisotropic sheet 24 to be at least 1500 W/mK and the thickness to be at least 50 μm, and more preferable for the thermal conductivity in directions across the X-Y plane to be at least 350 W/mK and the thickness to be at least 100 μm. It is also preferable for the thermal conductivity in directions across the X-Y plane of the thermally anisotropic sheet 24 to be at least 100 W/mK and the thickness to be at least 150 μm.

When the heat resistance temperature of the first insulating sheet 23 is 260° C., from the graph in FIG. 9, it is preferable for the thermal conductivity in directions across the X-Y plane of the thermally anisotropic sheet 24 to be at least 300 W/mK and the thickness to be at least 150 μm, and more preferable for the thermal conductivity in directions across the X-Y plane to be at least 100 W/mK and the thickness to be at least 200 μm.

Results of analysis when the heat resistance temperature of the first insulating sheet 23 is 260° C., the thermal conductivity of the thermally anisotropic sheet 24 in directions across the X-Y plane is 1000 W/mK, and the thickness is 300 μm are depicted in FIG. 11. FIG. 11 depicts how temperature propagates from a point P in the +X direction, the −Y direction, and the −Z direction. In the drawing, hatching with the same pattern indicates the same temperature. Areas that have not been hatched are not heated by the heat caused by laser welding, meaning that there is almost no change in temperature before and after laser welding.

From FIG. 11, it may be understood that in the connection members 40 and the second power terminals 25, heat propagates from the point P in the +X direction and the −Y direction. When this happens, the temperature falls as the distance from the point P increases.

In the connection members 40 and the second power terminals 25, temperature also propagates in the −Z direction. However, in the thermally anisotropic sheet 24, the temperature immediately below the point P is lower than the temperature at the point P in the connection members 40 and the second power terminals 25. The thermally anisotropic sheet 24 also conducts heat so that the temperature falls in the +X direction and the −Y direction from the position directly below the point P.

In addition, it was understood that although a slight rise in temperature was observed on the thermally anisotropic sheet 24 side of the first insulating sheet 23 located below (in the −Y direction) the thermally anisotropic sheet 24, there is no change in temperature in the first insulating sheet 23 as a whole. This is because the thermally anisotropic sheet 24 effectively conducts the heat caused by laser welding in directions across the X-Y plane, which slows down the propagation of heat in the −Z direction. This means that the thermally anisotropic sheet 24 widens the range where a rise in temperature occurs in the second power terminal 25 and the connection members 40, thereby suppressing the localized rise in temperature. In addition, the second power terminal 25 has higher thermal conductivity than the first insulating sheet 23 and is thicker than the first insulating sheet 23. This means that the amount of heat that propagates to the first insulating sheet 23 is suppressed, and the instantaneous maximum temperature of the first insulating sheet 23 is reduced. For the reasons given above, it is believed that this suppresses thermal damage to the first insulating sheet 23.

In addition, the case 21 of the semiconductor module 20 is integrally molded by laminating the first power terminals 22a, 22b, and 22c, the first insulating sheets 23a, 23b, and 23c, the thermally anisotropic sheet 24, and the second power terminals 25a, 25b, and 25c. When doing so, adhesive may be provided between the first insulating sheets 23a, 23b, and 23c and the thermally anisotropic sheet 24. In addition, to prevent displacements, the thermally anisotropic sheet 24 may be provided with a part that protrudes in the ±Y direction beyond the range indicated by the broken lines in FIG. 3, and also a part that overlaps the second power terminals 25a, 25b, and 25c in plan view. By doing so, the thermally anisotropic sheet 24 has increased area to be sandwiched by the case 21 and thus displacement of the thermally anisotropic sheet 24 from the terminal laminated portions 26a, 26b, and 26c is prevented.

As an alternative, a graphene film may be formed by printing on the first insulating sheet 23a, 23b, and 23c-sides of the second power terminals 25a, 25b, and 25c, as described in Japanese National Publication of International Patent Application No. 2019-52931 for example. The “thermally anisotropic sheet 24” in this case is directly formed on the second power terminals 25a, 25b, and 25c, and merely contacts the first insulating sheets 23a, 23b, and 23c.

The semiconductor module 20 described above includes terminal laminated portions 26a, 26b, and 26c in which the first power terminals 22a, 22b, and 22c, the first insulating sheets 23a, 23b, and 23c, and the second power terminals 25a, 25b, and 25c are respectively laminated in that order. The thermally anisotropic sheet 24 having thermal conductivity that is higher in directions on a plane perpendicular to the direction of lamination of the terminal laminated portions 26a, 26b, and 26c than in the lamination direction is provided between the first insulating sheets 23a, 23b, and 23c and the second power terminals 25a, 25b, and 25c. By using this configuration, when the connection members 40 are joined by laser welding to the front surfaces of the second power terminals 25a, 25b, and 25c, it is possible to suppress the propagation of the heat caused by the laser to the first insulating sheets 23a, 23b, and 23c. This means that it is possible to suppress the occurrence of damage to the first insulating sheets 23a, 23b, and 23c, so that the first power terminals 22a, 22b, and 22c and the second power terminals 25a, 25b, and 25c are kept insulated from each other. Accordingly, the occurrence of electrical defects for the semiconductor module 20 is suppressed, which prevents a drop in reliability of the semiconductor module 20 and of the semiconductor device 10 that includes the semiconductor module 20.

### Second Embodiment

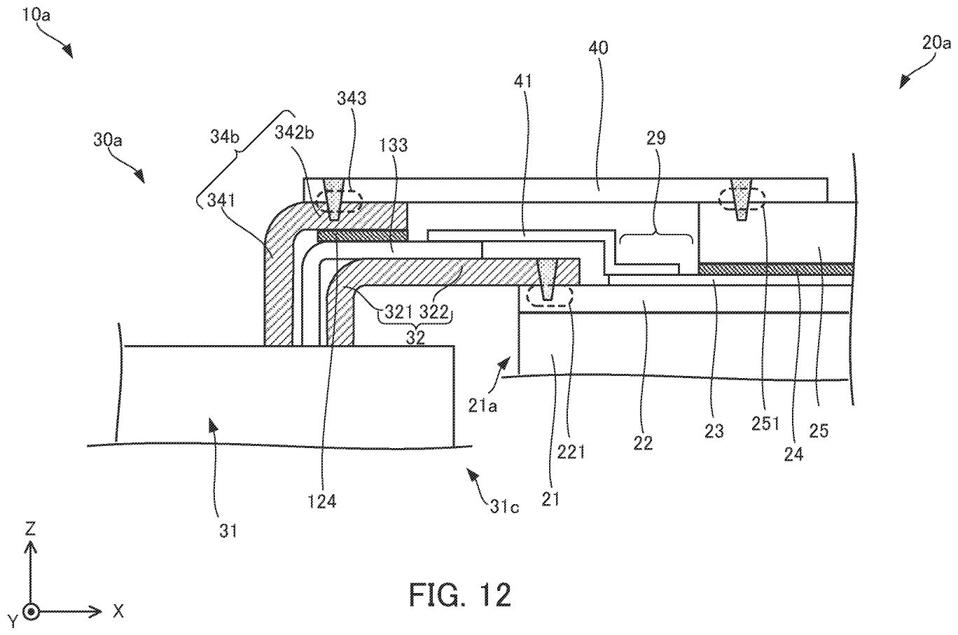

In the second embodiment, a semiconductor device 10a that differs to the semiconductor device 10 according to the first embodiment will be described with reference to FIG. 12. FIG. 12 is a cross-sectional view of connected portions in a semiconductor module according to the second embodiment. Note that FIG. 12 corresponds to a cross-sectional view of the semiconductor device 10 in FIG. 6 of the first embodiment. Note that in the second embodiment, configurations that are the same as those of the semiconductor device 10 according to the first embodiment have been assigned the same reference numerals, and description thereof is simplified or omitted.

The semiconductor device 10a includes a semiconductor module 20a and a capacitor 30a. In the semiconductor module 20a, an end portion of the first power terminal 22 extends so as to be flush with the first side portion 21a of the case 21. The remaining configuration of the semiconductor module 20a is the same as in the semiconductor module 20.

The capacitor 30a includes the first connection terminal 32, a second insulating sheet 133, and a second connection terminal 34b. The second connection terminal 34b in this case has the second conductive portion 341 and a second wiring portion 342b. The second wiring portion 342b of the capacitor 30a extends parallel to the first wiring portion 322 of the first connection terminal 32 toward the fifth side portion 31c to a position just before the fifth side portion 31c. The front surface of the second wiring portion 342b of the second connection terminal 34b and the front surface of the second power terminal 25 of the semiconductor module 20a are formed so as to be flush. The first end portions of the connection members 40 are joined to the second joining regions 251 on the front surfaces of the second power terminals 25, and the second end portions of the connection members 40 are joined to the third joining regions 343 on the front surface of the second wiring portion 342b. By doing so, the semiconductor module 20a and the capacitor 30a are electrically connected.

The second insulating sheet 133 extends from between the first connection terminal 32 and the second connection terminal 34b of the case 31. Note that in the configuration depicted in FIG. 12, the second insulating sheet 133 extends across the front surface of the first connection terminal 32. A front end portion of the second insulating sheet 133 is positioned between the front end portion of the first connection terminal 32 and the front end portion of the second connection terminal 34b. With this configuration, the first connection terminal 32 and the second connection terminal 34b are kept insulated from each other. A gap is formed between the front surface of the first wiring portion 322 of the first connection terminal 32 and the rear surfaces of the connection members 40. A third insulating sheet 41 is also provided in this gap. That is, the third insulating sheet 41 is located between the front end portion of the second insulating sheet 133, which is between the front end portion of the first connection terminal 32 and the front end portion of the second connection terminal 34b, and the front end portion of the first insulating sheet 23. Note that the third insulating sheet 41 is also made of the same material as the second insulating sheet 133. A first end portion of the third insulating sheet 41 is bonded to the terrace portion 29 of the first insulating sheet 23 and a second end portion of the third insulating sheet 41 is bonded to the front end portion of the second insulating sheet 133. When doing so, a known adhesive is used for the bonding. The end portion on the semiconductor module 20a-side of the third insulating sheet 41 is divided and shaped like the teeth of a comb in plan view in accordance with the housing regions 21e1, 21e2, and 21e3 of the semiconductor module 20a. The capacitor 30a-side end portion of the third insulating sheet 41 is formed with the same width or wider than the second insulating sheet 133 in plan view. Due to the second insulating sheet 133 and the third insulating sheet 41, the first connection terminal 32 is able to be kept insulated from the second connection terminal 34b and the connection members 40, and also from the second power terminals 25. Note that like the second insulating sheet 33 in FIG. 6, the second insulating sheet 133 may cover the first connection terminal 32 and may extend in that state as far as the first insulating sheet 23. With this configuration, the end portion on the semiconductor module 20a-side of the second insulating sheet 133 is shaped like the teeth of a comb in the same way as the second insulating sheet 33 in FIGS. 5A and 5B. In this case, the third insulating sheet 41 is not needed.

In the capacitor 30a, a thermally anisotropic sheet 124 is provided between the second insulating sheet 133 and the rear surface of the second connection terminal 34b (the second wiring portion 342b). The thermally anisotropic sheet 124 is made of the same material as the thermally anisotropic sheet 24. The fifth side portion 31c-side end portion of the thermally anisotropic sheet 124 is flush with the end portion of the second wiring portion 342b. An end portion of the thermally anisotropic sheet 124 on the opposite side to the fifth side portion 31c reaches as far as a position located above a straight portion of the second wiring portion 342b in FIG. 12. However, the end portion of the thermally anisotropic sheet 124 on the opposite side to the fifth side portion 31c may extend as far as the front surface side of the case 31. In a state where the thermally anisotropic sheet 124 is provided, the connection members 40 are laser-welded to the second connection terminal 34b (the second wiring portion 342b). Heat propagates from the laser-welded connection members 40 toward the case 31 side (in the −Z direction). Heat from the second wiring portion 342b is transmitted across the X-Y plane by the thermally anisotropic sheet 124, so that propagation to the second insulating sheet 133 is suppressed. This means that it is possible to suppress damage to the second insulating sheet 133 due to heat caused by laser welding. Accordingly, it is possible to keep the second connection terminal 34b and the first connection terminal 32 insulated from each other.

According to one aspect, the present embodiments suppress the occurrence of electrical defects, which prevents a drop in reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module, comprising:
a terminal laminated portion including a first terminal, an insulating member, and a second terminal that are laminated in that order to one another in a laminating direction; and
a thermally anisotropic member disposed between the insulating member and the second terminal, the thermally anisotropic member having a thermal conductivity that is higher in a planar direction perpendicular to the laminating direction than in the laminating direction.

2. The semiconductor module according to claim 1, wherein the thermally anisotropic member has a predetermined thickness and a predetermined thermal conductivity in the planar direction, so that a maximum temperature, when the second terminal is heated, of a surface of the thermally anisotropic member facing the insulating member is not greater than a heat resistance temperature of the insulating member.

3. The semiconductor module according to claim 2, wherein when the heat resistance temperature of the insulating member is 300° C., the thickness of the thermally anisotropic member is at least 50 μm but not greater than 200 μm.

4. The semiconductor module according to claim 3, wherein the thermal conductivity in the planar direction of the thermally anisotropic member is at least 1500 W/mK.

5. The semiconductor module according to claim 3, wherein the thickness of the thermally anisotropic member is at least 100 μm but not greater than 150 μm.

6. The semiconductor module according to claim 5, wherein the thermal conductivity in the planar direction of the thermally anisotropic member is at least 1000 W/mK.

7. The semiconductor module according to claim 2, wherein when the heat resistance temperature of the insulating member is 260° C., the thickness of the thermally anisotropic member is at least 150 μm.

8. The semiconductor module according to claim 7, wherein the thermal conductivity in the planar direction of the thermally anisotropic member is at least 300 W/mK.

9. The semiconductor module according to claim 7, wherein the thickness of the thermally anisotropic member is at least 200 μm.

10. The semiconductor module according to claim 9, wherein the thermal conductivity in the planar direction of the thermally anisotropic member is at least 100 W/mK.

11. The semiconductor module according to claim 2, wherein the thermally anisotropic member has graphite as a main component thereof.

12. The semiconductor module according to claim 1, wherein
the first terminal includes a first joining region on a front surface thereof, the front surface of the first terminal extending from the first terminal in a plan view of the semiconductor module,
the second terminal includes a second joining region on a front surface thereof,
the insulating member includes a terrace portion between the second terminal and the first joining region in the plan view, and
the semiconductor module further comprises a connection member that is joined to the second joining region.

13. The semiconductor module according to claim 12, wherein the thermally anisotropic member is provided directly below the connection member in the laminating direction.

14. The semiconductor module according to claim 13, wherein the thermally anisotropic member is provided so as to extend as far as an outer peripheral portion of the second terminal as a maximum in the plan view.

15. The semiconductor module according to claim 1, wherein the thermally anisotropic member is formed as a sheet.

16. The semiconductor module according to claim 1, wherein the thermally anisotropic member is formed on a rear surface of the second terminal and is provided between the second terminal and the insulating member.
